(19) United States
(12) Patent Application Publication
(10) Pub. No.: US 2021/0181621 A1
(43) Pub. Date: Jun. 17, 2021

(54) Systems and Methods for Curing an Imprinted Film

(71) Applicant: CANON KABUSHIKI KAISHA, Tokyo (JP)

(72) Inventors: Edward Brian Fletcher, Austin, TX (US); James W. Irving, Austin, TX (US); Nilabh K. Roy, Austin, TX (US)

(21) Appl. No.: 16/712,406

(22) Filed: Dec. 12, 2019

(51) Int. Cl. G03F 7/00

(52) U.S. Cl. CPC G03F 7/0002; H01L 21/67011

(57) ABSTRACT

Imprinting methods and imprinting systems configured to cure formable material between a substrate and a template. With a first spatial light modulator with a first set of modulation elements configured to expose the formable material between the substrate and the template to a first pattern of actinic radiation; and a second spatial light modulator with a second set of modulation elements configured to expose the formable material between the substrate and the template to a second pattern of actinic radiation. At a plane of the formable material, a first set of centers of the first pattern associated with centers of the first set of modulation elements may be offset from a second set of centers of the second pattern associated with centers of the second set of modulation elements.

### BACKGROUND OF INVENTION

### Technical Field

The present disclosure relates to systems and methods for curing an imprinted film.

### Description of the Related Art

Nano-fabrication includes the fabrication of very small structures that have features on the order of 100 nanometers or smaller. One application in which nano-fabrication has had a sizeable impact is in the fabrication of integrated circuits. The semiconductor processing industry continues to strive for larger production yields while increasing the circuits per unit area formed on a substrate. Improvements in nano-fabrication include providing greater process control and/or improving throughput while also allowing continued reduction of the minimum feature dimensions of the structures formed.

One nano-fabrication technique in use today is commonly referred to as nanoimprint lithography. Nanoimprint lithography is useful in a variety of applications including, for example, fabricating one or more layers of integrated devices by shaping a film on a substrate. Examples of an integrated device include but are not limited to CMOS logic, microprocessors, NAND Flash memory, NOR Flash memory, DRAM memory, MRAM, 3D cross-point memory, Re-RAM, Fe-RAM, SU-RAM, MEMS, and the like. Exemplary nanoimprint lithography systems and processes are described in detail in numerous publications, such as U.S. Pat. Nos. 8,349,241, 8,066,930, and 6,936,194, all of which are hereby incorporated by reference herein.

The nanoimprint lithography technique disclosed in each of the aforementioned patents describes the shaping of a film on a substrate by the formation of a relief pattern in a formable material (polymerizable) layer. The shape of this film may then be used to transfer a pattern corresponding to the relief pattern into and/or onto an underlying substrate.

The shaping process uses a template spaced apart from the substrate and the formable material is applied between the template and the substrate. The template is brought into contact with the formable material causing the formable material to spread and fill the space between the template and the substrate. The formable liquid is solidified to form a film that has a shape (pattern) conforming to a shape of the surface of the template that is in contact with the formable liquid. After solidification, the template is separated from the solidified layer such that the template and the substrate are spaced apart.

The substrate and the solidified layer may then be subjected to additional processes, such as etching processes, to transfer an image into the substrate that corresponds to the pattern in one or both of the solidified layer and/or patterned layers that are underneath the solidified layer. The patterned substrate can be further subjected to known steps and processes for device (article) fabrication, including, for example, curing, oxidation, layer formation, deposition, doping, planarization, etching, formable material removal, dicing, bonding, and packaging, and the like.

### SUMMARY OF THE INVENTION

A first embodiment, may be an imprinting system configured to cure formable material between a substrate and a template. The system may comprise: a first spatial light modulator with a first set of modulation elements configured to expose the formable material between the substrate and the template to a first pattern of actinic radiation; and a second spatial light modulator with a second set of modulation elements configured to expose the formable material between the substrate and the template to a second pattern of actinic radiation. At a plane of the formable material, a first set of centers of the first pattern associated with centers of the first set of modulation elements may be offset from a second set of centers of the second pattern associated with centers of the second set of modulation elements.

In an aspect of the first embodiment, the first pattern maybe in focus at the plane of the formable material and the second pattern maybe not in focus at the plane of the formable material.

In an aspect of the first embodiment, a difference between a first projected pitch of the first pattern at the plane of the formable material and a second projected pitch of the second pattern at the plane of the formable material may be less than 10% of the first projected pitch.

In an aspect of the first embodiment, the first pattern at the plane of the formable material includes a first set of interstitial points. Each of the interstitial points in the first set of interstitial points is located equidistant between groups of neighboring subpatterns of the first set of centers. The second set of centers may be aligned with the first set of interstitial points at the plane of the formable material.

In an aspect of the first embodiment, an average distance between the first set of interstitial point and the second set of centers may be less than 10% of an average projected pitch of the first pattern at the plane of the formable material.

In an aspect of the first embodiment, the first spatial light modulator and the second light modulator may each include: a digital micromirror device (DMD); a liquid crystal on silicon (LCoS) device; or a liquid crystal display (LCD).

The first embodiment, may further comprise a beam combiner. The beam combiner may combine actinic radiation from the first spatial light modulator and actinic radiation from the second spatial light modulator into a combined beam. The combined beam may be guided to the formable material between the template and the substrate.

In an aspect of the first embodiment, at the beam combiner, the first set of centers may be offset from the second set of centers.

The first embodiment, may further comprise one or more optical components positioned between the first spatial light modulator and the beam combiner. The first pattern of actinic radiation includes a first set of subpatterns. Each particular subpattern in the first set of subpatterns is associated with a particular modulation element of the first spatial light modulator. The second pattern of actinic radiation includes a second set of subpatterns. Each particular subpattern in the second set of subpatterns is associated a particular modulation element of the second spatial light modulator. The one or more optical components may be configured to control a first average size of subpatterns in the first set of subpatterns to be greater than a second average size of subpatterns in the second set of subpatterns.

In an aspect of the first embodiment, the one or more optical components maybe configured to control a difference between a first projected pitch of the first pattern at the plane of the formable material and a second projected pitch of the second pattern at the plane of the formable material to be less than 10% of the first projected pitch.

In an aspect of the first embodiment, a first average image plane of the modulation elements of the first spatial light modulator maybe positioned a first distance from the plane of the formable material. A second average image plane of the modulation elements of the second spatial light modulator maybe positioned a second distance from the plane of the formable material. The second distance maybe greater than the first distance.

In an aspect of the first embodiment, a first average projected pitch at the plane of the formable material of modulation elements of the first spatial light modulator maybe within 10% of a second average projected pitch at the plane of the formable material of modulation elements of the second spatial light modulator.

The first embodiment, may further comprise: a template chuck configured to hold the template; a substrate chuck configured to hold the substrate; a dispensing system configured to dispense the formable material onto the substrate; a positioning system configured to bring the template into contact with formable material; a first actinic radiation emitter configured to illuminate the first spatial light modulator; a second actinic radiation emitter configured to illuminate the second spatial light modulator; and a third actinic radiation emitter configured to illuminate formable material between template and the substrate with actinic radiation which has not been modulated by the first spatial light modulation and the second light modulator.

A second embodiment, may be an imprinting method configured to cure formable material between a substrate and a template. The method may comprise exposing the formable material between the substrate and the template to a first pattern of actinic radiation from a first spatial light modulator with a first set of modulation elements. The method may further comprise exposing the formable material between the substrate and the template to a second pattern of actinic radiation from a second spatial light modulator with a second set of modulation elements. At a plane of the formable material, a first set of centers of the first pattern associated with centers of the first set of modulation elements maybe offset from a second set of centers of the second pattern associated with centers of the second set of modulation elements.

The second embodiment, may also include a method of manufacturing an article using the imprinting method according to claim 14, the of manufacturing an article may further comprise: processing the cured formable material on the substrate; and forming the article from the processed substrate.

These and other objects, features, and advantages of the present disclosure will become apparent upon reading the following detailed description of exemplary embodiments of the present disclosure, when taken in conjunction with the appended drawings, and provided claims.

### BRIEF DESCRIPTION OF THE FIGURES

So that features and advantages of the present invention can be understood in detail, a more particular description of embodiments of the invention may be had by reference to the embodiments illustrated in the appended drawings. It is to be noted, however, that the appended drawings only illustrate typical embodiments of the invention and are therefore not to be considered limiting of its scope, for the invention may admit to other equally effective embodiments.

FIG. 1 is an illustration of an exemplary nanoimprint lithography system having a template with a mesa spaced apart from a substrate as used in an embodiment.

FIG. 2 is an illustration of an exemplary template that may be used in an embodiment.

FIG. 3 is a flowchart illustrating an exemplary imprinting method as used in an embodiment.

FIGS. 4A-D are illustrations of arrangements of particular components of an exemplary nanoimprint lithography system as used in embodiments.

FIG. 5A is an illustration of modulation elements and an idealized spatial distribution of actinic radiation associated with the modulation elements used in embodiments.

FIGS. 5B-G are information representing a measured spatial distribution of actinic radiation supplied by modulation elements as used in embodiments.

FIG. 5H is a micrograph illustrating a cured film as produced by nanoimprint lithography system with a single spatial light modulator.

FIGS. 6A-I are simulated spatial distributions of actinic radiation as used in embodiments.

Throughout the figures, the same reference numerals and characters, unless otherwise stated, are used to denote like features, elements, components or portions of the illustrated embodiments. Moreover, while the subject disclosure will now be described in detail with reference to the figures, it is done so in connection with the illustrative exemplary embodiments. It is intended that changes and modifications can be made to the described exemplary embodiments without departing from the true scope and spirit of the subject disclosure as defined by the appended claims.

### DETAILED DESCRIPTION

The nanoimprint lithography technique can be used to shape a film on a substrate from a formable material. The shaping process includes bringing a shaping surface (patterning surface) of a template into contact with formable material on a substrate. The shaping process also includes exposing the formable material to actinic radiation which causes the formable material to cure.

The applicant has found it useful to have precise control over the spatio-temporal distribution of the actinic radiation during the curing process. One method of having precise control over the actinic radiation is to use a spatial light modulator (SLM) that has a plurality of modulation elements. Each modulation element of the SLM can be individually controlled. Which allows adjustment of the spatio-temporal distribution of the actinic radiation on a modulation element by modulation element basis. The SLM is configured to transform a beam of radiation from a radiation source into a set of beamlets. Each beamlet associated with a modulation element of the SLM.

The SLM can add unwanted artifacts to the spatio-temporal distribution of the actinic radiation due to inter-element variations in the intensity (reductions in intensity between beamlets). What is needed are systems and/or methods for compensating for these inter-element variations while still maintaining the advantages of SLMs ability to control spatio-temporal distribution of the actinic radiation.

Nanoimprint System (Shaping System)

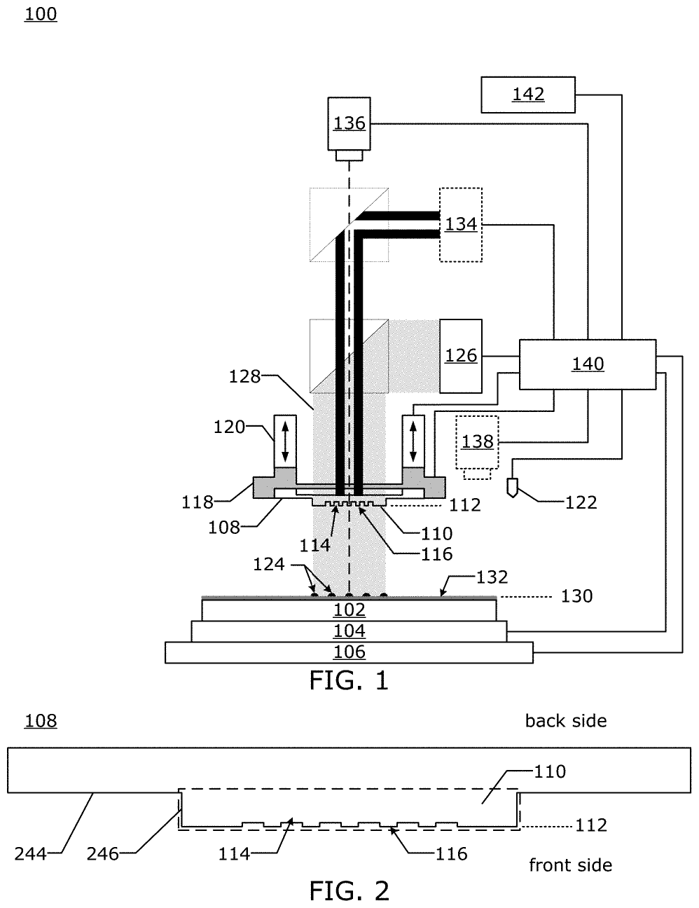

FIG. 1 is an illustration of a nanoimprint lithography system 100 in which an embodiment may be implemented. The nanoimprint lithography system 100 is used to produce an imprinted (shaped) film on a substrate 102. The substrate 102 may be coupled to a substrate chuck 104. The substrate chuck 104 may be but is not limited to a vacuum chuck, pin-type chuck, groove-type chuck, electrostatic chuck, electromagnetic chuck, and/or the like.

The substrate 102 and the substrate chuck 104 may be further supported by a substrate positioning stage 106. The substrate positioning stage 106 may provide translational and/or rotational motion along one or more of the x, y, z, θ, ψ, and φ-axes. The substrate positioning stage 106, the substrate 102, and the substrate chuck 104 may also be positioned on a base (not shown). The substrate positioning stage may be a part of a positioning system.

Spaced-apart from the substrate 102 is a template 108. The template 108 may include a body having a mesa (also referred to as a mold) 110 extending towards the substrate 102 on a front side of the template 108. The mesa 110 may have a patterning surface 112 thereon also on the front side of the template 108. The patterning surface 112, also known as a shaping surface, is the surface of the template that shapes the formable material 124. In an embodiment, the patterning surface 112 is planar and is used to planarize the formable material. Alternatively, the template 108 may be formed without the mesa 110, in which case the surface of the template facing the substrate 102 is equivalent to the mold 110 and the patterning surface 112 is that surface of the template 108 facing the substrate 102.

The template 108 may be formed from such materials including, but not limited to, fused-silica, quartz, silicon, organic polymers, siloxane polymers, borosilicate glass, fluorocarbon polymers, metal, hardened sapphire, and/or the like. The patterning surface 112 may have features defined by a plurality of spaced-apart template recesses 114 and/or template protrusions 116. The patterning surface 112 defines a pattern that forms the basis of a pattern to be formed on the substrate 102. In an alternative embodiment, the patterning surface 112 is featureless in which case a planar surface is formed on the substrate. In an alternative embodiment, the patterning surface 112 is featureless and the same size as the substrate and a planar surface is formed across the entire substrate.

Template 108 may be coupled to a template chuck 118. The template chuck 118 may be, but is not limited to, vacuum chuck, pin-type chuck, groove-type chuck, electrostatic chuck, electromagnetic chuck, and/or other similar chuck types. The template chuck 118 may be configured to apply stress, pressure, and/or strain to template 108 that varies across the template 108. The template chuck 118 may include piezoelectric actuators which can squeeze and/or stretch different portions of the template 108. The template chuck 118 may include a system such as a zone based vacuum chuck, an actuator array, a pressure bladder, etc. which can apply a pressure differential to a back surface of the template causing the template to bend and deform.

The template chuck 118 may be coupled to an imprint head 120 which is a part of the positioning system. The imprint head may be moveably coupled to a bridge. The imprint head 120 may include one or more actuators such as voice coil motors, piezoelectric motors, linear motor, nut and screw motor, etc., which are configured to move the template chuck 118 relative to the substrate in at least the z-axis direction, and potentially other directions (e.g. x, y, θ, ψ, and φ-axes).

The nanoimprint lithography system 100 may further comprise a fluid dispenser 122. The fluid dispenser 122 may also be moveably coupled to the bridge. In an embodiment, the fluid dispenser 122 and the imprint head 120 share one or more or all positioning components. In an alternative embodiment, the fluid dispenser 122 and the imprint head 120 move independently from each other. The fluid dispenser 122 may be used to deposit liquid formable material 124 (e.g., polymerizable material) onto the substrate 102 in a pattern. Additional formable material 124 may also be added to the substrate 102 using techniques, such as, drop dispense, spin-coating, dip coating, chemical vapor deposition (CVD), physical vapor deposition (PVD), thin film deposition, thick film deposition, and/or the like prior to the formable material 124 being deposited onto the substrate 102. The formable material 124 may be dispensed upon the substrate 102 before and/or after a desired volume is defined between the mold 112 and the substrate 102 depending on design considerations. The formable material 124 may comprise a mixture including a monomer as described in U.S. Pat. Nos. 7,157,036 and 8,076,386, both of which are herein incorporated by reference.

Different fluid dispensers 122 may use different technologies to dispense formable material 124. When the formable material 124 is jettable, ink jet type dispensers may be used to dispense the formable material. For example, thermal ink jetting, microelectromechanical systems (MEMS) based ink jetting, valve jet, and piezoelectric ink jetting are common techniques for dispensing jettable liquids.

The nanoimprint lithography system 100 may further comprise a curing system that includes at least a radiation source 126 that directs actinic energy along an exposure path 128. The imprint head and the substrate positioning stage 106 may be configured to position the template 108 and the substrate 102 in superimposition with the exposure path 128. The radiation source 126 sends the actinic energy along the exposure path 128 after the template 108 has contacted the formable material 128. FIG. 1 illustrates the exposure path 128 when the template 108 is not in contact with the formable material 124, this is done for illustrative purposes so that the relative position of the individual components can be easily identified. An individual skilled in the art would understand that exposure path 128 would not substantially change when the template 108 is brought into contact with the formable material 124.

The nanoimprint lithography system 100 may further comprise a field camera 136 that is positioned to view the spread of formable material 124 after the template 108 has made contact with the formable material 124. FIG. 1 illustrates an optical axis of the field camera's imaging field as a dashed line. As illustrated in FIG. 1 the nanoimprint lithography system 100 may include one or more optical components (dichroic mirrors, beam combiners, prisms, lenses, mirrors, etc.) which combine the actinic radiation with light to be detected by the field camera. The field camera 136 may be configured to detect the spread of formable material under the template 108. The optical axis of the field camera 136 as illustrated in FIG. 1 is straight but may be bent by one or more optical components. The field camera 136 may include one or more of a CCD, a sensor array, a line camera, and a photodetector which are configured to gather light that has a wavelength that shows a contrast between regions underneath the template 108 that are in contact with the formable material, and regions underneath the template 108 which are not in contact with the formable material 124. The field camera 136 may be configured to gather monochromatic images of visible light. The field camera 136 may be configured to provide images of the spread of formable material 124 underneath the template 108; the separation of the template 108 from cured formable material; and can be used to keep track of the imprinting process. The field camera 136 may also be configured to measure interference fringes, which change as the formable material spreads 124 between the gap between the patterning surface 112 and the substrate surface 130.

The nanoimprint lithography system 100 may further comprise a droplet inspection system 138 that is separate from the field camera 136. The droplet inspection system 138 may include one or more of a CCD, a camera, a line camera, and a photodetector. The droplet inspection system 138 may include one or more optical components such as a lenses, mirrors, apertures, filters, prisms, polarizers, windows, adaptive optics, and/or light sources. The droplet inspection system 138 may be positioned to inspect droplets prior to the patterning surface 112 contacting the formable material 124 on the substrate 102.

The nanoimprint lithography system 100 may further include a thermal radiation emitter 134 which may be configured to provide a spatial distribution of thermal radiation to one or both of the template 108 and the substrate 102. The thermal radiation emitter 134 may include one or more sources of thermal electromagnetic radiation that will heat up one or both of the substrate 102 and the template 108 and does not cause the formable material 124 to solidify. The thermal radiation emitter 134 may include a spatial light modulator such as a digital micromirror device (DMD), Liquid Crystal on Silicon (LCoS), Liquid Crystal Device (LCD), etc., to modulate the spatio-temporal distribution of thermal radiation. The nanoimprint lithography system 100 may further comprise one or more optical components which are used to combine the actinic radiation, the thermal radiation, and the radiation gathered by the field camera 136 onto a single optical path that intersects with the imprint field when the template 108 comes into contact with the formable material 124 on the substrate 102. The thermal radiation emitter 134 may send the thermal radiation along a thermal radiation path (which in FIG. 1 is illustrated as 2 thick dark lines) after the template 108 has contacted the formable material 128. FIG. 1 illustrates the thermal radiation path when the template 108 is not in contact with the formable material 124, this is done for illustrative purposes so that the relative position of the individual components can be easily identified. An individual skilled in the art would understand that the thermal radiation path would not substantially change when the template 108 is brought into contact with the formable material 124. In FIG. 1 the thermal radiation path is shown terminating at the template 108, but it may also terminate at the substrate 102. In an alternative embodiment, the thermal radiation emitter 134 is underneath the substrate 102, and thermal radiation path is not combined with the actinic radiation and the visible light.

Prior to the formable material 124 being dispensed onto the substrate, a substrate coating 132 may be applied to the substrate 102. In an embodiment, the substrate coating 132 may be an adhesion layer. In an embodiment, the substrate coating 132 may be applied to the substrate 102 prior to the substrate being loaded onto the substrate chuck 104. In an alternative embodiment, the substrate coating 132 may be applied to substrate 102 while the substrate 102 is on the substrate chuck 104. In an embodiment, the substrate coating 132 may be applied by spin coating, dip coating, etc. In an embodiment, the substrate 102 may be a semiconductor wafer. In another embodiment, the substrate 102 may be a blank template (replica blank) that may be used to create a daughter template after being imprinted.

The nanoimprint lithography system 100 may include an imprint field atmosphere control system such as gas and/or vacuum system, an example of which is described in U.S. Patent Publication Nos. 2010/0096764 and 2019/0101823 which are hereby incorporated by reference. The gas and/or vacuum system may include one or more of pumps, valves, solenoids, gas sources, gas tubing, etc. which are configured to cause one or more different gases to flow at different times and different regions. The gas and/or vacuum system may be connected to a first gas transport system that transports gas to and from the edge of the substrate 102 and controls the imprint field atmosphere by controlling the flow of gas at the edge of the substrate 102. The gas and/or vacuum system may be connected to a second gas transport system that transports gas to and from the edge of the template 108 and controls the imprint field atmosphere by controlling the flow of gas at the edge of the template 108. The gas and/or vacuum system may be connected to a third gas transport system that transports gas to and from the top of the template 108 and controls the imprint field atmosphere by controlling the flow of gas through the template 108. One or more of the first, second, and third gas transport systems may be used in combination or separately to control the flow of gas in and around the imprint field.

The nanoimprint lithography system 100 may be regulated, controlled, and/or directed by one or more processors 140 (controller) in communication with one or more components and/or subsystems such as the substrate chuck 104, the substrate positioning stage 106, the template chuck 118, the imprint head 120, the fluid dispenser 122, the radiation source 126, the thermal radiation emitter 134, the field camera 136, imprint field atmosphere control system, and/or the droplet inspection system 138. The processor 140 may operate based on instructions in a computer readable program stored in a non-transitory computer readable memory 142. The processor 140 may be or include one or more of a CPU, MPU, GPU, ASIC, FPGA, DSP, and a general-purpose computer. The processor 140 may be a purpose-built controller or may be a general-purpose computing device that is adapted to be a controller. Examples of a non-transitory computer readable memory include but are not limited to RAM, ROM, CD, DVD, Blu-Ray, hard drive, networked attached storage (NAS), an intranet connected non-transitory computer readable storage device, and an internet connected non-transitory computer readable storage device.

Either the imprint head 120, the substrate positioning stage 106, or both varies a distance between the mold 110 and the substrate 102 to define a desired space (a bounded physical extent in three dimensions) that is filled with the formable material 124. For example, the imprint head 120 may apply a force to the template 108 such that mold 110 is in contact with the formable material 124. After the desired volume is filled with the formable material 124, the radiation source 126 produces actinic radiation (e.g. UV, 248 nm, 280 nm, 350 nm, 365 nm, 395 nm, 400 nm, 405 nm, 435 nm, etc.) causing formable material 124 to cure, solidify, and/or cross-link; conforming to a shape of the substrate surface 130 and the patterning surface 112, defining a patterned layer on the substrate 102. The formable material 124 is cured while the template 108 is in contact with formable material 124, forming the patterned layer on the substrate 102. Thus, the nanoimprint lithography system 100 uses an imprinting process to form the patterned layer which has recesses and protrusions which are an inverse of the pattern in the patterning surface 112. In an alternative embodiment, the nanoimprint lithography system 100 uses an imprinting process to form a planar layer with a featureless patterning surface 112.

The imprinting process may be done repeatedly in a plurality of imprint fields (also known as just fields or shots) that are spread across the substrate surface 130. Each of the imprint fields may be the same size as the mesa 110 or just the pattern area of the mesa 110. The pattern area of the mesa 110 is a region of the patterning surface 112 which is used to imprint patterns on a substrate 102 which are features of the device or are then used in subsequent processes to form features of the device. The pattern area of the mesa 110 may or may not include mass velocity variation features (fluid control features) which are used to prevent extrusions from forming on imprint field edges. In an alternative embodiment, the substrate 102 has only one imprint field which is the same size as the substrate 102 or the area of the substrate 102 which is to be patterned with the mesa 110. In an alternative embodiment, the imprint fields overlap. Some of the imprint fields may be partial imprint fields which intersect with a boundary of the substrate 102.

The patterned layer may be formed such that it has a residual layer having a residual layer thickness (RLT) that is a minimum thickness of formable material 124 between the substrate surface 130 and the patterning surface 112 in each imprint field. The patterned layer may also include one or more features such as protrusions which extend above the residual layer having a thickness. These protrusions match the recesses 114 in the mesa 110.

Template

FIG. 2 is an illustration of a template 108 that may be used in an embodiment. The patterning surface 112 may be on a mesa 110 (identified by the dashed box in FIG. 2). The mesa 110 is surrounded by a recessed surface 244 on the front side of the template. Mesa sidewalls 246 connect the recessed surface 244 to patterning surface 112 of the mesa 110. The mesa sidewalls 246 surround the mesa 110. In an embodiment in which the mesa is round or has rounded corners, the mesa sidewalls 246 refers to a single mesa sidewall that is a continuous wall without corners. In an embodiment, the mesa sidewalls 246 may have one or more of a perpendicular profile; an angled profile; a curved profile; a staircase profile; a sigmoid profile; a convex profile; or a profile that is combination of those profiles.

Imprinting Process

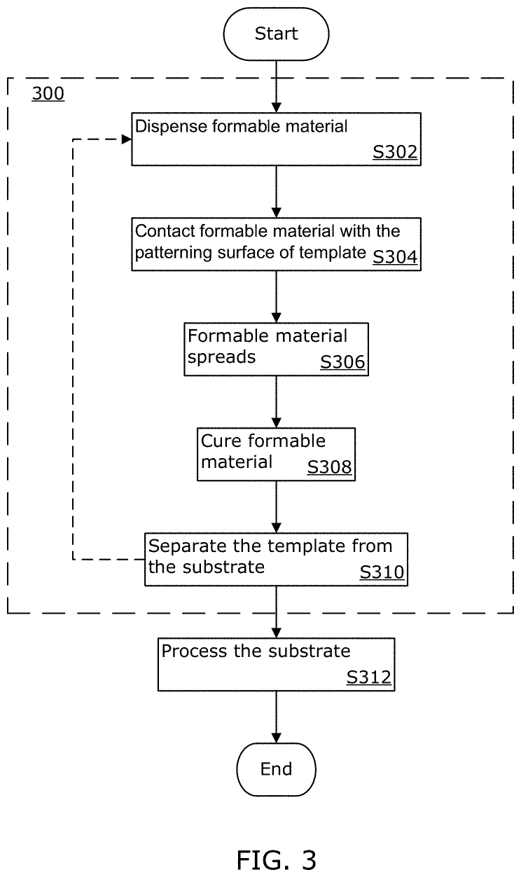

FIG. 3 is a flowchart of a method of manufacturing an article (device) that includes an imprinting process 300 by the nanoimprint lithography system 100 that can be used to form patterns in formable material 124 on one or more imprint fields (also referred to as: pattern areas or shot areas). The imprinting process 300 may be performed repeatedly on a plurality of substrates 102 by the nanoimprint lithography system 100. The processor 140 may be used to control the imprinting process 300.

In an alternative embodiment, the imprinting process 300 is used to planarize the substrate 102. In which case, the patterning surface 112 is featureless and may also be the same size or larger than the substrate 102.

The beginning of the imprinting process 300 may include a template mounting step causing a template conveyance mechanism to mount a template 108 onto the template chuck 118. The imprinting process may also include a substrate mounting step, the processor 140 may cause a substrate conveyance mechanism to mount the substrate 102 onto the substrate chuck 104. The substrate may have one or more coatings and/or structures. The order in which the template 108 and the substrate 102 are mounted onto the nanoimprint lithography system 100 is not particularly limited, and the template 108 and the substrate 102 may be mounted sequentially or simultaneously.

In a positioning step, the processor 140 may cause one or both of the substrate positioning stage 106 and/or a dispenser positioning stage to move an imprinting field i (index i may be initially set to 1) of the substrate 102 to a fluid dispense position below the fluid dispenser 122. The substrate 102, may be divided into N imprinting fields, wherein each imprinting field is identified by an index i. In which N is a real integer such as 1, 10, 75, etc. {N∈ [symbol] ⁺}. In a dispensing step S302, the processor 140 may cause the fluid dispenser 122 to dispense formable material onto an imprinting field i. In an embodiment, the fluid dispenser 122 dispenses the formable material 124 as a plurality of droplets. The fluid dispenser 122 may include one nozzle or multiple nozzles. The fluid dispenser 122 may eject formable material 124 from the one or more nozzles simultaneously. The imprint field i may be moved relative to the fluid dispenser 122 while the fluid dispenser is ejecting formable material 124. Thus, the time at which some of the droplets land on the substrate may vary across the imprint field i. In an embodiment, during the dispensing step S302, the formable material 124 may be dispensed onto a substrate in accordance with a drop pattern. The drop pattern may include information such as one or more of position to deposit drops of formable material, the volume of the drops of formable material, type of formable material, shape parameters of the drops of formable material, etc. In an embodiment, the drop pattern may include only the volumes of the drops to be dispensed and the location of where to deposit the droplets.

After, the droplets are dispensed, then a contacting step S304 may be initiated, the processor 140 may cause one or both of the substrate positioning stage 106 and a template positioning stage to bring the patterning surface 112 of the template 108 into contact with the formable material 124 in imprint field i.

During a spreading step S306, the formable material 124 then spreads out towards the edge of the imprint field i and the mesa sidewalls 246. The edge of the imprint field may be defined by the mesa sidewalls 246. How the formable material 124 spreads and fills the mesa can be observed via the field camera 136 and may be used to track a progress of a fluid front of formable material.

In a curing step S308, the processor 140 may send instructions to the radiation source 126 to send a curing illumination pattern of actinic radiation through the template 108, the mesa 110 and the patterning surface 112. The curing illumination pattern provides enough energy to cure (polymerize) the formable material 124 under the patterning surface 112.

In a separation step S310, the processor 140 uses one or more of the substrate chuck 104, the substrate positioning stage 106, template chuck 118, and the imprint head 120 to separate the patterning surface 112 of the template 108 from the cured formable material on the substrate 102. If there are additional imprint fields to be imprinted, then the process moves back to step S302.

In an embodiment, after the imprinting process 300 is finished additional semiconductor manufacturing processing is performed on the substrate 102 in a processing step S312 so as to create an article of manufacture (e.g. semiconductor device). In an embodiment, each imprint field includes a plurality of devices.

The further semiconductor manufacturing processing in processing step S312 may include etching processes to transfer a relief image into the substrate that corresponds to the pattern in the patterned layer or an inverse of that pattern. The further processing in processing step S312 may also include known steps and processes for article fabrication, including, for example, inspection, curing, oxidation, layer formation, deposition, doping, planarization, etching, formable material removal, dicing, bonding, packaging, and the like. The substrate 102 may be processed to produce a plurality of articles (devices).

Radiation Source

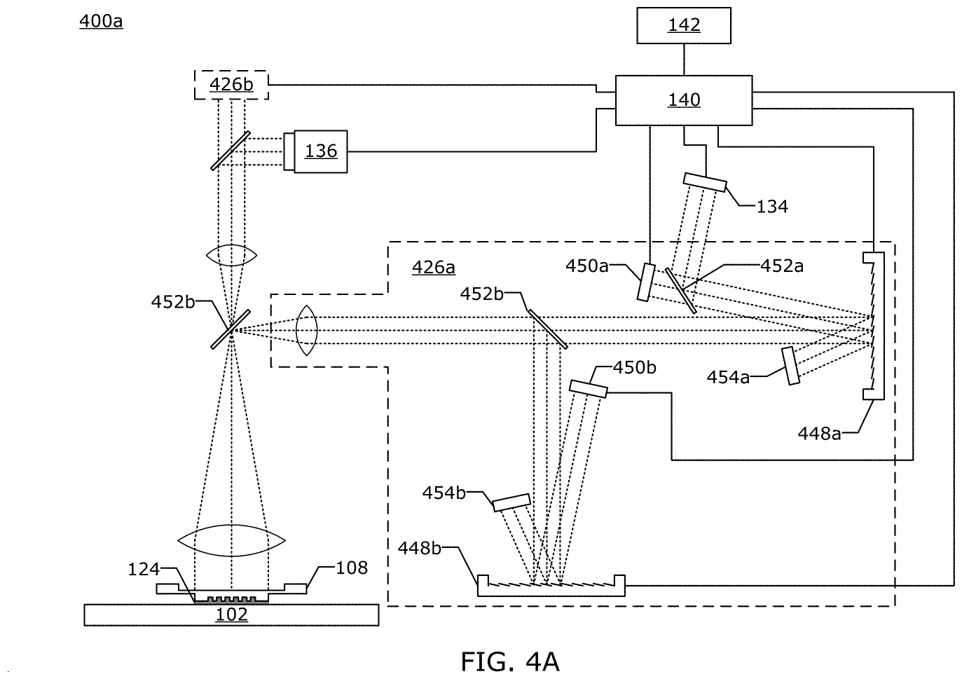

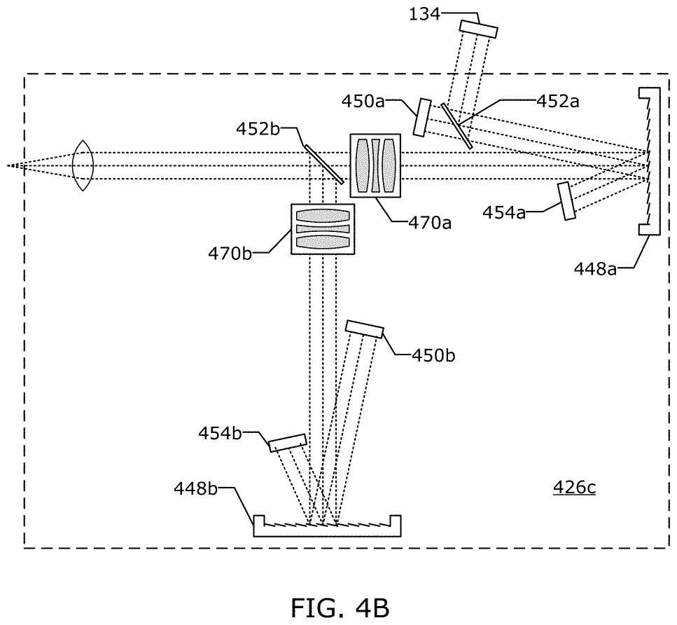

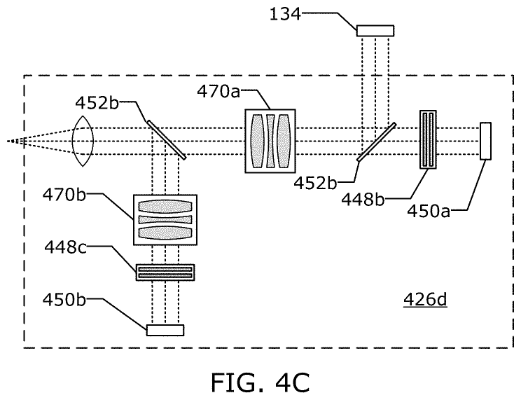

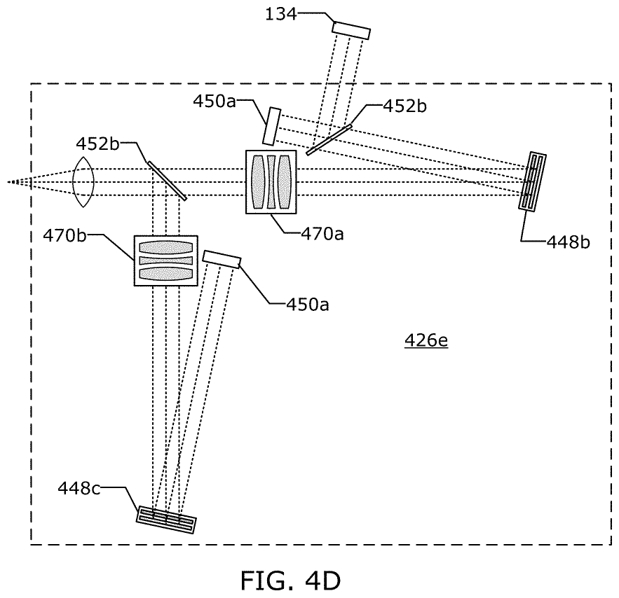

FIG. 4A is an illustration of a nanoimprint lithography system 400 that is substantially similar to the nanoimprint lithography system 100 illustrated in FIG. 1 in which additional components of the first source of actinic radiation 426a is illustrated. Some of the elements of nanoimprint lithography system 400 are not illustrated in order to clarify the arrangement of components within the radiation source. The order, arrangement, and use of optical components such as light sources, beam splitters, lenses, and mirrors as illustrated in FIG. 4A are exemplary and other arrangements of optical components can be used to carry out an embodiment.

The nanoimprint lithography system 400a may include a first source of actinic radiation 426a and/or a second source of actinic radiation 426b. The first source of actinic radiation 426a may include a first light emitter 450a which may be a laser, LED, or a lamp. The first light emitter 450a is positioned to illuminate a first spatial light modulator 448a. One or more optical components may be arranged to guide the actinic radiation to the first spatial light modulator 448a. The first light emitter 450a may receive one or more signals from the processor 140 with instructions on when and how much actinic radiation to provide.

The spatial light modulator(s) 448(a-b) may be digital micromirror device (DMD), Liquid Crystal on Silicon (LCoS), Liquid Crystal Device (LCD), spatial light valve, mirror array, MOEMS, diffractive MEMS, etc., which modulate the spatio-temporal distribution of actinic radiation from the first light emitter 450a. The nanoimprint lithography system 400a may include one or more optical components which guide actinic radiation from the first spatial light modulator 448a through the patterning surface 112 and to the formable material 124 between the patterning surface 112 and the substrate surface 130.

The nanoimprint lithography system 400a may include a first beam combiner 452a which combines thermal radiation from a thermal radiation emitter 134 with an actinic radiation from the first light emitter 450a. The first beam combiner 452a combines thermal radiation and actinic radiation into a single combined light source which is then guided towards the spatial light first modulator 448a. Examples of the first beam combiner 452a may be a dichroic beam combiner, a prism, a polarization beam combiner, a partially silvered mirror, an optical switch, an optical coupler, etc. In an embodiment, the first spatial light modulator 448a is time multiplexed such that it may be used to provide a thermal radiation pattern for a first period of time and a first actinic radiation pattern for a second period of time.

As illustrated in FIG. 4A the first spatial light modulator 448a may be a DMD. The DMD may include individual mirrors (modulation elements) on the spatial light modulator 448a that may be in a first state that guides light towards the patterning surface 112 or in a second state that guides the light away from the patterning surface 112 for example towards a first beam dump 454a.

The first source of actinic radiation 426a may include a second light emitter 450b which may be a laser, LED, or a lamp. The second light emitter 450b is positioned to illuminate a second spatial light modulator 448b (such as the DMD illustrated in FIG. 4A). One or more optical components may be arranged to guide the actinic radiation from the second light emitter 450b to the second spatial light modulator 448b. The second light emitter 450b may receive one or more signals from the processor 140 with instructions on when and how much actinic radiation to provide.

The second spatial light modulator 448b is substantially similar to the first spatial light modulator 448a and may be a DMD. The DMD may include individual mirrors (modulation elements) on the second spatial light modulator 448b that may be in a first state that guides light towards the patterning surface 112 or in a second state that guides the light away from the patterning surface 112 for example towards a second beam dump 454b. In an embodiment, there is only one beam dump and the first spatial light modulator and the second spatial light modulator both guide light towards a shared beam dump.

The first source of actinic radiation 426a includes a second beam combiner 452b. The second beam combiner 452b is arranged to combine actinic radiation from the first spatial light modulator 448a with actinic radiation from the second spatial light modulator 448b into a first combined beam. Examples of the second beam combiner 452b may be a dichroic beam combiner, a prism, a polarization beam combiner, a partially silvered mirror, etc. One or more optical components may then guide the first combined beam to the formable material 124 between the patterning surface 112 and substrate surface 130. The first combined beam may also be combined with other beam of radiation.

The spatial light modulators 448(a-b) include a plurality of modulation elements that are tiled across the spatial light modulator 448. Each modulation element may be individually addressable in both space and time. The processor 140 may be configured to send sets of signals to the spatial light modulators 448(a-b) based on a map of modulation values received from the memory 142. In response to the first set of signals the spatial light modulator 448 will change the state of individual modulation elements in the spatial light modulator. In an embodiment, the map of modulation values is information indicating on/off status of each modulation element of the spatial light modulator 448 (DMD, LCD, LCoS). In an embodiment, the map of modulation is information indicating the status of each modulation element of the spatial light modulator 448 (DMD, LCD, LCoS). The status associated with each modulation element includes one or more of: on/off status; on/off status duration; amount reflected (for reflective LCD); amount transmitted (for transmitted LCD).

In the case in which the spatial light modulator is a DMD changing the state of a modulation element means moving a micromirror from a first angle to a second angle. In the case in which the spatial light modulator 448 is a transmissive spatial light modulator, such as an LCD or a spatial light valve, changing the state of a modulation element means changing the transmissivity of the modulation element. Changing the transmissivity may include changing the state of a polarization retarder (for example a liquid crystal). The polarization retarder may include or be optically coupled to a polarizer which block some portion of the light. In the case in which the spatial light modulator 448 is a reflective spatial light modulator, such as an LCoS, changing the state of a modulation element means changing the reflectivity of the modulation element. Changing the transmissivity may include changing the state of a polarization retarder (for example a liquid crystal) on a reflective surface. The polarization retarder may include or be optically coupled to a polarizer which blocks some portion of the light.

FIG. 4B is an illustration of an embodiment that includes a third source of actinic radiation 426c that replaces the first source of actinic radiation and includes one or both of a first set of optical components 470a and a second set of optical components 470b. In an embodiment, the first set of optical components 470a is configured to control a first average size of the set of projected images of the modulation elements of the first SLM 448a at the plane of the formable material. In an embodiment, the average size of the set of projected images of the modulation elements of the first SLM 448a at the plane of the formable material are configured to be greater than a second average size of the projected images of the modulation elements of the second SLM 448b at the plane of the formable material. In an embodiment, one or both of the first and second sets of optical components 470a-b are configured to control the relative sizes of the projected images of the modulation elements at the plane of the formable material to have different sizes.

In an embodiment, one or both of the first and second sets of optical components 470a-b are configured to control the relative projected pitches of the projected images of the modulation elements at the plane of the formable material to have identical projected pitches of the projected images of the modulation elements. In an embodiment, the one or more optical components are configured to control both the relative sizes of the projected images of the optical components to be different in size while controlling the projected pitches of the projected images to be the same.

In an embodiment, the one or more optical components are configured to control locations of an image plane for each modulation element of each SLM 448a-b. In an embodiment, the image plane for each modulation element is not at the same location due to distortions in the optical system. There is an average image plane associated with each SLM that is averaged over the modulation elements. In an embodiment, the one or more optical components are configured to control an average location of a first image plane of the images of the modulation elements of the first SLM 448a to have a first distance from the plane of the formable material. In an embodiment, the one or more optical components are configured to control a location of a second image plane of the images of the modulation elements of the second SLM 448b to have a second distance from the plane of the formable material. In an embodiment, the first distance is different from the second distance. In an embodiment, an image plane difference between the first distance and the second distance is greater than 5 mm.

In an embodiment, the one or more optical components are configured such that the differences in the projected pitches is less than a threshold while the an image plane difference is greater than a second threshold.

FIG. 4C is an illustration of an embodiment that includes a fourth source of actinic radiation 426d that replaces the third source of actinic radiation 426c and the spatial light modulators 448a-b are transmissive spatial light modulators 448c-d such as LCDs. The transmissive spatial light modulators 448c-d may include a spatio-temporally addressable liquid crystal polarization retarder and a polarizer. The transmissive spatial light modulators 448b may include MEMS based spatio-temporally addressable light valves.

FIG. 4D is an illustration of an embodiment that includes a fifth source of actinic radiation 426e that replaces the third source of actinic radiation 426c and the spatial light modulators 448a-b with reflective spatial intensity modulators 448d-e such as a LCoS device. The reflective spatial light modulators 448d-e may include a spatio-temporally addressable liquid crystal polarization retarder, a polarizer, and a reflective surface such as silicon. The reflective spatial intensity modulators 448d-e may include a MEMS based spatio-temporally addressable reflective surface.

The spatial light modulators 448 are positioned to illuminate the formable material 124 under the template 108 with a spatio-temporal distribution of energy (J/m²) in accordance with signals received from the processor 140 which are representative of a map of modulation values (for e.g. intensity & duty cycles). The actinic radiation cures or helps cure the formable material 124 under the template 108. An embodiment may include one or more optical components such as lenses, mirror, apertures, etc. which guide the radiation from the spatial light modulators 448 to the formable material 124. An embodiment may include one or more optical components which help match the shape of the active area of the spatial light modulator 448 to the shape of the mesa 110. An embodiment may include one or more optical components which adjust the position of the focal plane of the actinic radiation from the spatial light modulator relative to formable material 124.

In an embodiment, the one or more optical components may expand the light from the SLM by a factor of: 5×; 4.8×; 4.6×; 4.4×; 4.2×; 4.4×; 4.2×; 4.0×; 3.0×; 2.5×; 2×; 1.5×; etc. In an embodiment, the one or more optical components match the field of the modulation elements of the SLM with the approximate size of the patterning surface 112. For example, the field of the modulation elements for a DMD type SLM may be 14.0×10.5, 19.3×12.1, 20.7×11.6 mm and the imprint field may be 26×33 mm requiring that the magnification be greater than 2 or more. An LCD type SLM may be larger than the imprint field requiring that the one or more of the optical components shrinks the image produced by the SLM by a factor of: 0.8×; 0.5×; 0.1×; etc.

In an embodiment, an image of the one or both the first SLM 448a or the second SLM 448b are focused at the plane of the formable material. In an embodiment, the light from the first SLM 448a is expanded by a first magnification factor and light from the second SLM 448b is expanded by a second different magnification factor. In an embodiment, the size of the modulation elements in the first SLM 448a is different from the size of the modulation elements in the second SLM 448b.

An embodiment, may include a second source of actinic radiation 426b which has not been modulated by either of the first or second spatial light modulators that is guided to the plane of the formable material 124. Actinic radiation from the second source of actinic radiation 426b is guided by one or more optical components to the formable material 124. The second source of actinic radiation 426b may have the same or different wavelength from the first source of actinic radiation 426a. An embodiment may include a third beam combiner 452c (such as prisms, partially silvered mirrors, dichroic filters, etc.) which combines light from the first actinic radiation source 426a and the second source of actinic radiation 426b. In an embodiment, actinic radiation from each of the radiation sources may be directed at the formable material 124 from a different angle.

In an embodiment, the second source of actinic radiation 426b is configured to illuminate a central portion of the patterning surface 112 and the first source of actinic radiation 426a is configured illuminate the outer edges of the patterning surface 112 near the mesa sidewalls 246.

An embodiment, may include a field camera 136 which monitors the formable material under the template 108 and may control the timing of the illumination of the formable material 124 with actinic radiation. An embodiment may include a fourth beam combiner 452d which may be used to combine gathered light with any of the beams which direct actinic radiation towards the formable material 124 under the patterning surface 112.

Spatial Light Modulator

In an embodiment, the fill factor of the spatial light modulator 448(a-b) is less than 100%. The fill factor of SLMs can vary significantly depending on the modulation technology used by the SLM and are typically found to be in the 70-99% range. The applicant has found that artifacts can be formed in the cured formable material due to an SLM with a less than 100% fill factor. The applicant has found that the impact of these artifacts can be mitigated by using a second spatial light modulator.

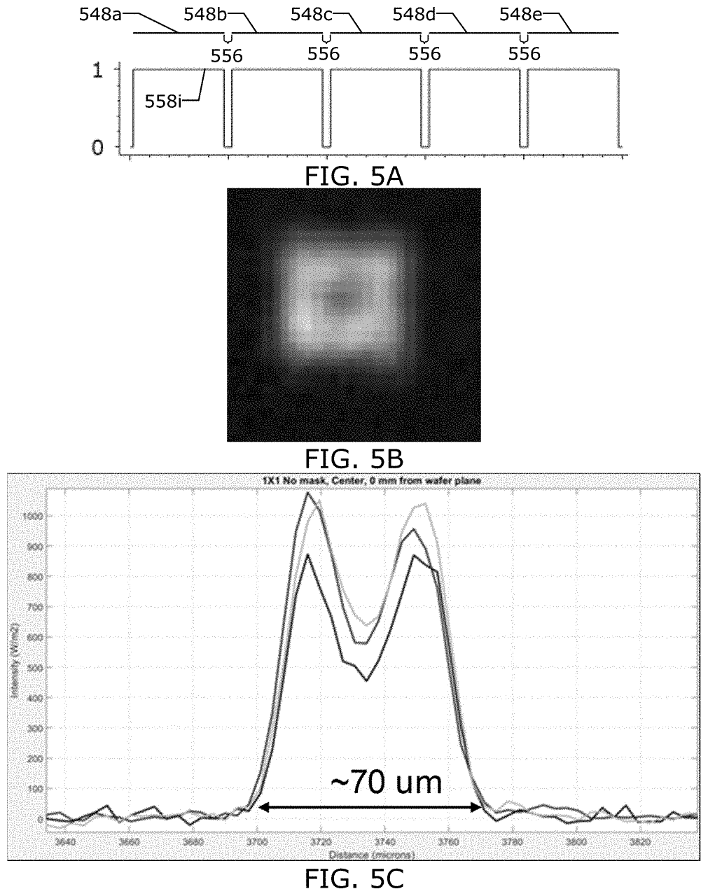

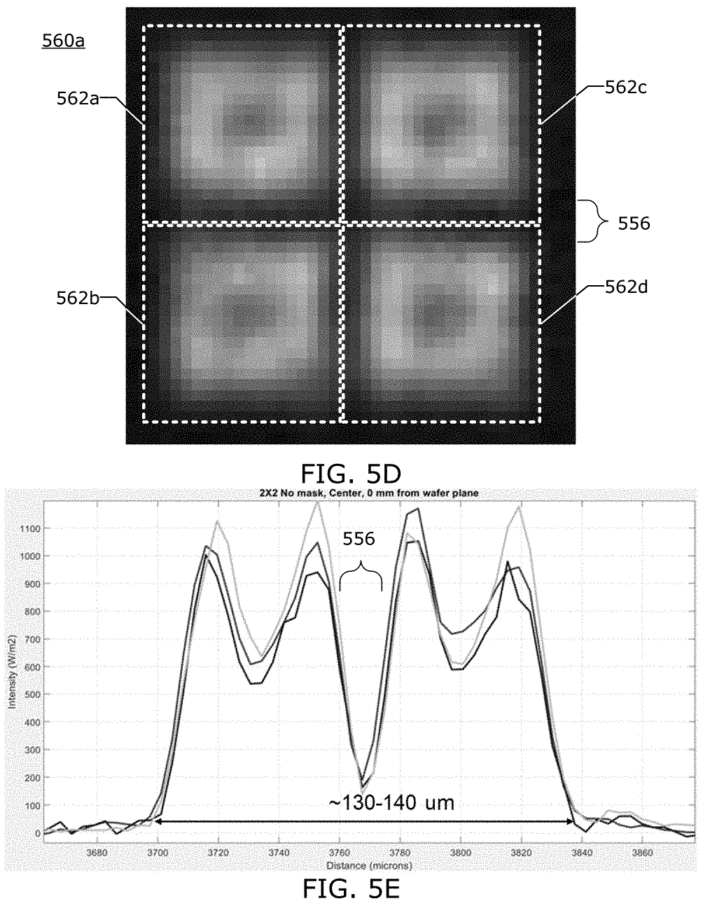

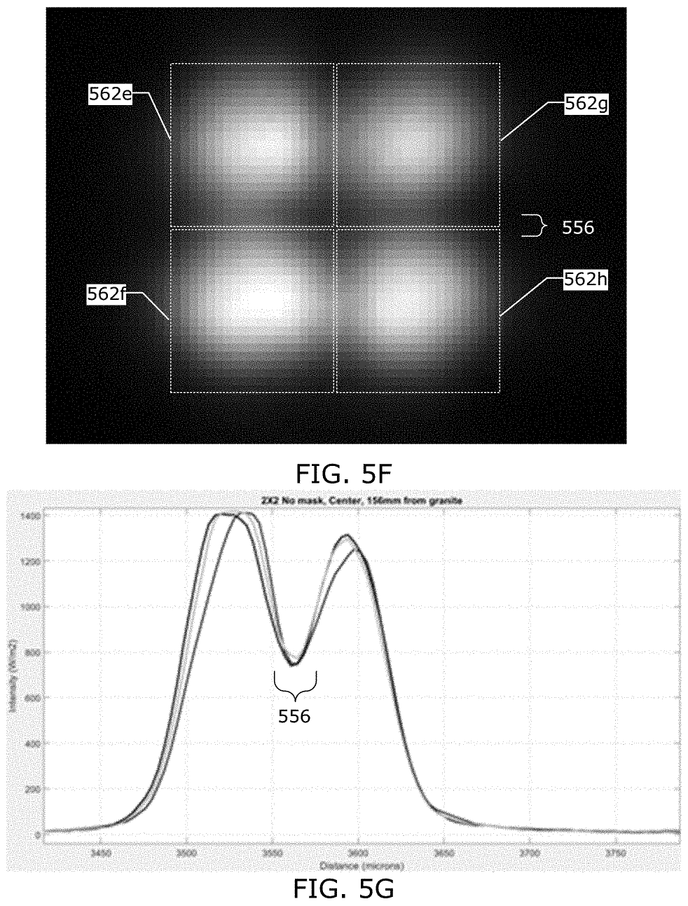

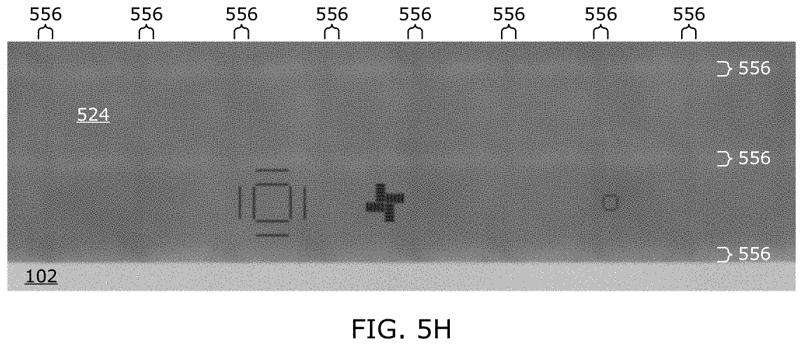

FIG. 5A is an illustration of the active areas of 5 exemplary modulation elements (548a, 548b, 548c, 548d, and 548e) in a spatial light modulator with a 92% fill factor. In between each modulation element is an interstitial area 556. FIG. 5A also illustrates a cross section of an idealized actinic radiant intensity pattern 558 at the formable material 124 under the template 108, in the case where the five modulation elements 548a-e are turned on and perfectly focused at the plane of the formable material.

FIG. 5B is a measured intensity map of an irradiation pattern produced by a single beamlet of a single modulation element of a DMD type SLM 448(a-b) when it is focused at the plane of the formable material. FIG. 5C is a plot showing cross sections of the measured intensity data in the intensity map data shown in FIG. 5B. Note the grey center in the middle of the image is from the support post that provides the hinge on which the mirror associated with an individual modulation element of the DMD is pivoted.

FIG. 5D is a measured intensity map of an irradiation pattern produced by four beamlets of four neighboring modulation elements of a DMD type SLM 448(a-b) when it is focused at the plane of the formable material. FIG. 5D is an example of a projected focused pattern 560a made up of four projected focused subpatterns 562a-d. FIG. 5E is a plot showing cross sections of the measured intensity data in the intensity map data shown in FIG. 5D. Note the black cross between individual modulation elements in FIG. 5D showing the interstitial area 556.

FIG. 5F is a measured intensity map of an irradiation pattern produced by those four beamlets of four neighboring modulation elements of a DMD type SLM 448(a-b) when it is defocused at the plane of the formable material. FIG. 5F is an example of a projected defocused pattern 560b made up of four projected defocused subpatterns 562e-h. FIG. 5G is a plot showing cross sections of the measured intensity data in the intensity map data shown in FIG. 5F. Note that when the irradiation pattern is defocused the grey center spot associated with each modulation element is not detectable. Also note that the intensity of the irradiation in the interstitial area 556 is increased. In addition, the rate at which the intensity of the defocused beam drops off from the peak decreases relative to a more focused beam shown in FIG. 5E. Thus, defocusing improves the uniformity of the irradiation but, also decreases the rate at which the intensity drops off from beamlets near the mesa sidewall 246, which reduces the ability to control the edges of the beamlet intensity profile precisely.

FIG. 5H is a micrograph of a cured film 524 on a substrate 102. The cured film 524 includes three features shown as black areas of the micrograph. The cured film 524 includes undercured regions in the interstitial areas 556. These undercured regions can impact the ability to inspect and identify defects. Sometimes these undercured regions can also impact the ability to transfer patterns into the substrate in subsequent processing steps S312.

Modulation elements such as micromirrors in a DMD array of DMD type SLM may have a 0.3-1 μm gap between them (depending on the DMD device). These gaps (interstitial areas 556) between modulation elements allow the micromirrors to be rotated freely between two operational states (off/on) and a non-operational state parked.

In an embodiment, the one or more optical components guides sets of beamlets of light that is reflected from the micromirror surface when it is one of the operational states to the formable material 124 under the patterning surface 112 and blocks a substantial amount of light that is reflected and scattered from the gaps and micromirror surface when they are in the other operational state or parked.

When the one or more optical components focus the modulation elements of the SLMs 448(a-b) onto the formable material 124 under the patterning surface 112 gaps between the modulation elements are revealed in the cured film 524 as grid lines (interstitial area 556) as illustrated in FIG. 5H.

Grid lines 556 between each modulation element are visible in the cured film 524 because the lower dose of actinic radiation at those locations results in less curing. This may result in the evaporation of features and reduction of RLT after separation of the template 108 from the cured film 524.

In an embodiment, in which an SLM image is magnified at the plane of the formable material, dead zones between the modulation elements are also magnified. Furthermore, diffraction of light can occur at edges of modulation element. The applicant has found that the intensity of actinic radiation in these interstitial areas 556 at the plane of the formable material is not zero but is reduced as illustrated in FIGS. 5D-G.

In an embodiment, the low intensity light between adjacent mirrors may be measured by an image sensor in the same plane as the formable material or through other means. Measuring the low intensity light in the interstitial regions may be used for calibrating compensation for this low intensity light.

The applicant has found that when the beamlets of actinic radiation is sufficiently defocused at the plane of the formable material the impact of the lower intensity of the actinic radiation in the interstitial area 556 is reduced. There is less shrinkage and the grid lines in the interstitial area 556 becomes less apparent when inspecting these images. The downside of defocusing is that there is less control of the actinic radiation at the edges of the formable material which impacts extrusion control.

FIG. 5H shows a micrograph of the cured film 524 on a substrate 102. The interstitial area 556 has a lower intensity then the rest of the cured film. The interstitial area 556 has an RLT and pillar height that has been reduced by 1-4 nm.

These differences in curing of the cured film in the interstitial area 556 relative to the rest of the cured film 524 are evident by the lighter color horizontal and vertical lines as illustrated in FIG. 5H. The contrast in the micrograph may be detected as a defect by an automated inspection tools even if the features in those areas are acceptable for pattern transfer process. The amount of “noise” that this causes for the fine feature inspection raises issues because actual defects of interest become more difficult to detect.

Exposure time is one of the process steps that affect the throughput of the nanoimprint lithography system 100. It is beneficial to reduce exposure time to increase productivity of the tool. The minimum exposure time which can adequately cure the formable material 124 for acceptable defectivity or pattern transfer becomes limited and defined by those regions receiving the lower intensity in the interstitial area 524.

Formable material 124 which received the lowest dose compared to formable material 124 which received the highest dose may have different mechanical properties (modulus, elongation, etc.) which results in either separation defects or defects during pattern transfer process (reactive ion etching etch rate differences, thickness differences, solvent swelling, evaporation of under-cured film during high temp bake, etc.). A cured film 524 with features having uniform mechanical and etch properties is preferable for process stability and predictable quality and yield.

Defocusing the actinic radiation coming from the SLM is one solution but comes at the price of extrusion control. One of the advantages of using an SLM in a nanoimprint lithography system 100 is to improve the spatial control of the dose of actinic radiation that formable material receives when it is near the mesa sidewalls 246 and when it is not under the patterning surface 112. This advantage is reduced when the actinic radiation from the SLM is defocused.

Arrangement of Two Spatial Light Modulators

The applicant has determined that variation in the actinic radiation dosage received by the formable material can be alleviated by the use of two spatial light modulators. In order to reduce the variation, the radiation patterns from the two separate spatial light modulators may be arranged in a particular manner that reduces the variation.

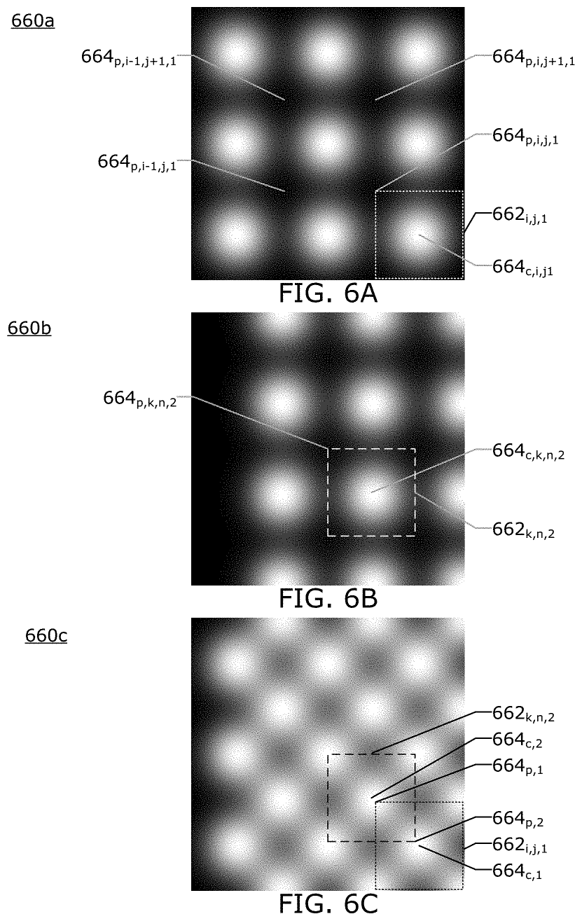

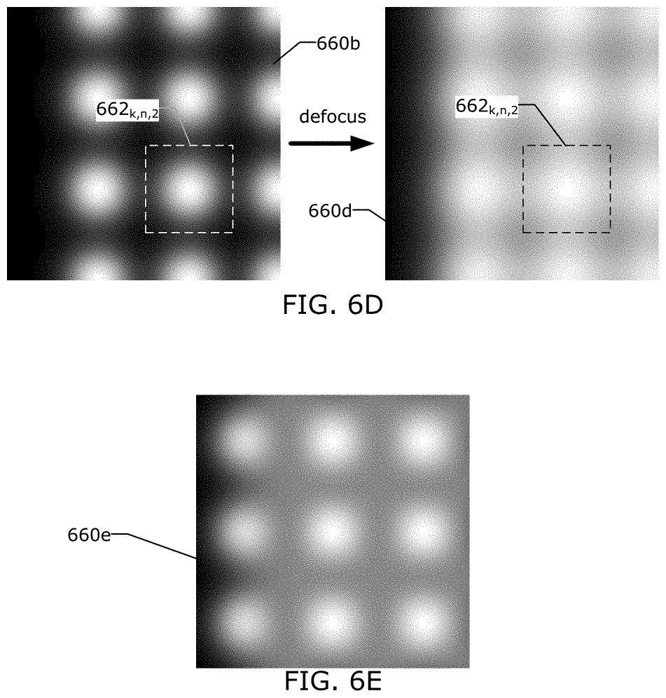

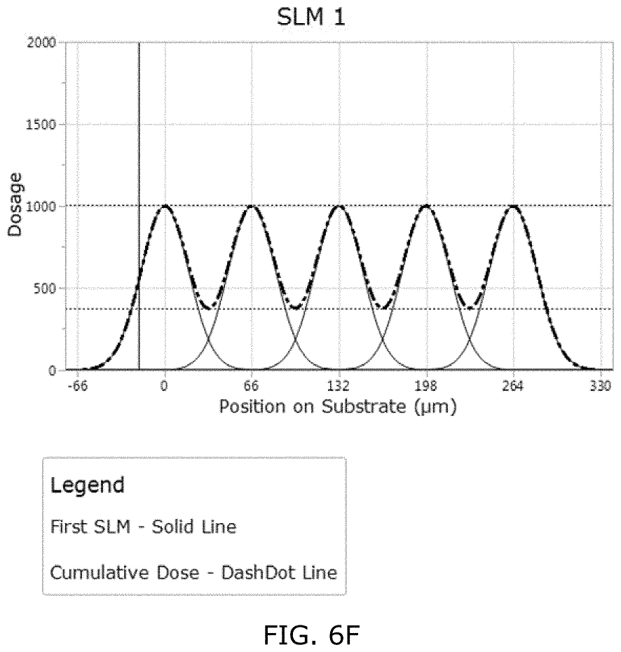

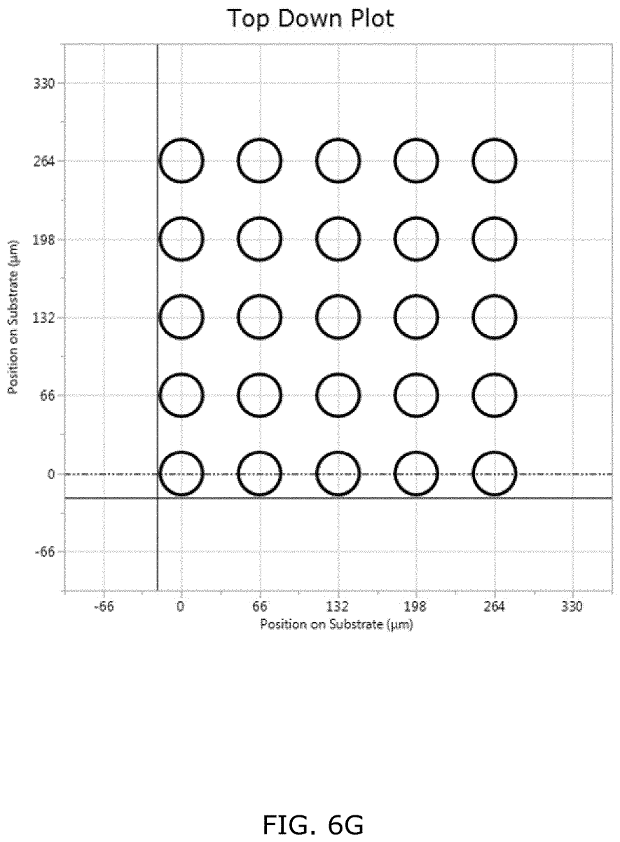

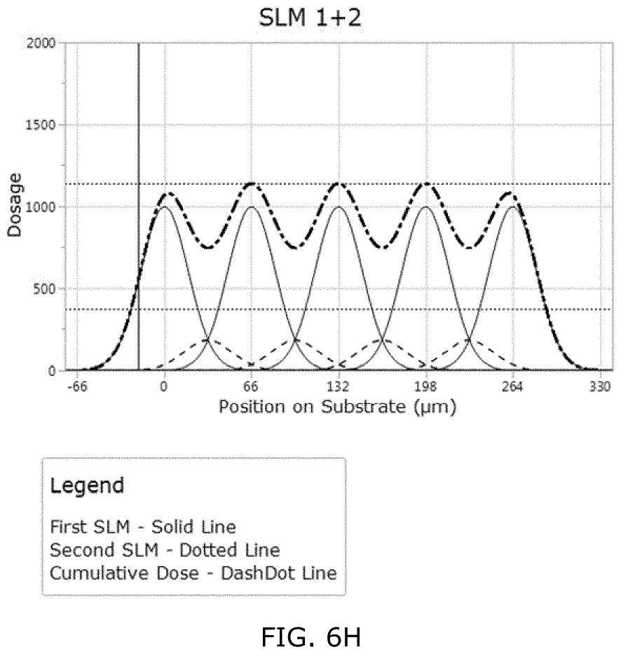

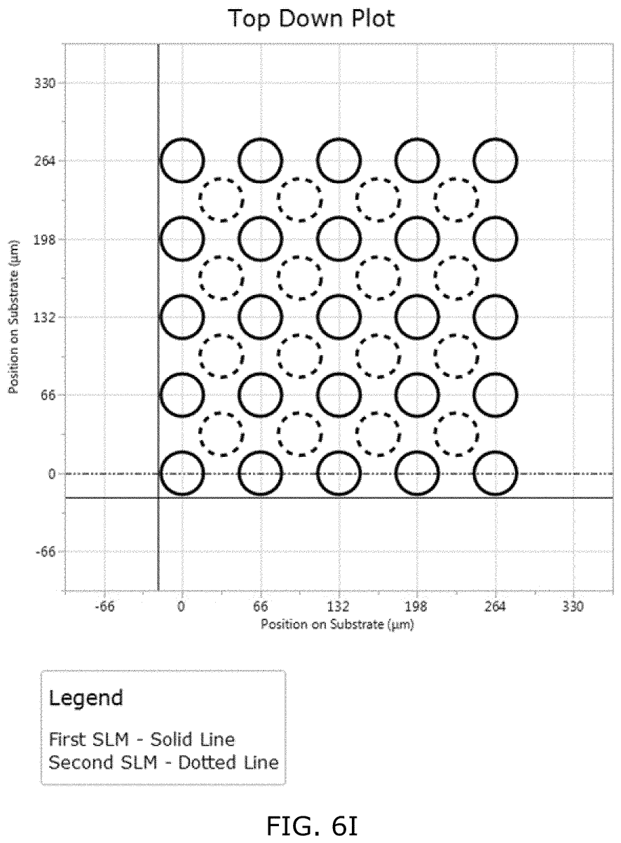

FIG. 6A is an illustration of a first simulated actinic radiation pattern 660a as would be received by formable material when 9 modulation elements of the first SLM 448a are in the on position and form a set of 9 beamlets. Each modulation element of the first SLM 448a is associated with a particular region of formable material. For example, particular modulation element M_{i,j,1} at address i,j of SLM 1 is associated with subpattern 662_{i,j,1} as outlined with a dotted box in FIG. 6A. In the simulation illustrated in FIG. 6A Each subpattern 662_{i,j,1} is represented by a Gaussian intensity distribution with a standard deviation of 15 μm tiled on a pitch of 66 μm. Each subpattern has a center point 664_{c,i,j,1} that is associated with the center of the subpattern 662_{i,j,1} as illustrated in FIG. 6A. Each set of four subpatterns of the first SLM 448a has an interstitial point 664_{p,i,j,1} centered between each of four neighboring subpatterns. There is a first set of subpatterns 662₁ that are tiled across the image produced at the plane of the formable material by the first SLM 448a. There is a first set of center points 664₀ that are also tiled across the image produced at the plane of the formable material by the first SLM 448a centered on each subpattern. There is a first set of interstitial points 664_{p,1} that are also tiled across the image produced at the plane of the formable material by the first SLM 448a at the intersections of four subpatterns.

FIG. 6B is an illustration of a second simulated actinic radiation pattern 660b as would be received by formable material when 12 modulation elements of the second SLM 448b are in the on position forming a set of 12 beamlets. Each modulation element of the second SLM 448b is associated with a particular region of formable material. For example, a particular modulation element M_{k,n,2} at an address k,n of SLM 2 is associated with subpattern 662_{k,n,2} as outlined with a dashed box in FIG. 6B. Each subpattern 662_{k,n,2} is represented by a Gaussian intensity distribution with a standard deviation of 15 μm in the simulation illustrated in FIG. 6A tiled on a pitch of 66 μm. Each subpattern has a center point 664_{c,k,n,2} that is associated with the center of the subpattern as illustrated in FIG. 6B. Each set of four subpatterns of the second SLM 448b has an interstitial point 664_{p,k,n,2} centered between each of four neighboring subpatterns. There is a second set of subpatterns 662₂ that are tiled across the image produced at the plane of the formable material by the second SLM 448b. There is a second set of center points 664_{c,2} that are also tiled across the image produced at the plane of the formable material by the second SLM 448b centered on each subpattern. There is a second set of interstitial points 664_{p,2} that are also tiled across the image produced at the plane of the formable material by the second SLM 448b at the intersections of four subpatterns.

FIG. 6C is an illustration of a simulated combined actinic radiation pattern 660c in which the first simulated actinic radiation pattern 660a and the second simulated actinic radiation pattern 660b are overlaid over each other. The radiation patterns (660a and 660b) are aligned such that the second set of center points 664_{c,2} of the subpatterns of the second simulated actinic radiation pattern 660b are substantially aligned with the first set of interstitial points 664_{p,1} of the first simulated actinic radiation pattern 660a. In an embodiment, the alignment accuracy of the second set of center points 664_{c,2} with the first set of interstitial points 664_{p,1} is better near the mesa sidewalls than near the center of patterning surface. In the context of the present disclosure, aligned means within the alignment capability of the optical system projecting images of the modulation elements onto the plane of the formable material.

In an embodiment, there is a first set of first projected subpatterns that are tiled with a first pitch to from a first projected pattern of actinic radiation at the plane of the formable material produced by the first SLM. There is also a second set of second projected subpatterns that are tiled with a second pitch to from a second projected pattern of actinic radiation at the plane of the formable material produced by the second SLM. In an embodiment, the difference between the first pitch and the second pitch is less than 10% of the first pitch.

There are a first set of center points positioned at the center of each projected subpattern in the first set of projected subpatterns. There are a second set of center points positioned at the center of each projected subpattern in the second set of projected subpatterns. There are a first set of interstitial points positioned equidistant from center points of neighboring projected subpatterns in the first set of projected subpatterns. There are 4 neighboring projected subpatterns for square modulation elements, this number can change depending on the shape of the modulation element. There are a second set of interstitial points positioned equidistant between neighboring projected subpatterns in the second set of projected subpatterns.

In an embodiment, a distance between a first set of interstitial points and a second set of center points is less than 6.5 μm. In an embodiment, a distance between a first set of interstitial points and a second set of center points is less than 10% of the first pitch. In an embodiment, a distance between a first set of interstitial points and a second set of centers is less than 10% of the second pitch.

In an embodiment, the first projected subpattern is focused at the plane of the formable material and the second projected pattern is defocused at the plane of the formable material. The second set of subpatterns are also defocused and include intensity peaks that are positioned near the first set of interstitial points in the interior of the patterning area. The second set of subpatterns are arranged so that do not cure formable material outside the mesa sidewalls do not project outside the patterning region

In an embodiment, there is a lens assembly for changing magnification placed in the projection path after the actinic radiation is reflected or transmitted by each of the SLMs.

FIG. 6D is an illustration of the second simulated actinic radiation pattern 660b that is defocused to obtain a third defocused simulated actinic radiation pattern 660d as would be received by formable material when 12 modulation elements of the second SLM 448b are in the on position and the radiation pattern is not focused at the plane of the formable material. In an embodiment, the focal plane of the second SLM 448b is above or below the focal plane of the first SLM 448a, while the magnification of the first SLM 448a is the same as the second SLM 448b at the plane of the formable material. Each subpattern 662_{k,n,2} is also defocused forming a defocused subpattern 668_{k,n,2} that is tiled across the patterning surface 112 which is the second set of defocused subpatterns 668₂. In the simulation illustrated in FIG. 6D, each defocused subpattern 662_{k,n,2} is represented by a Gaussian intensity distribution with a standard deviation of 25 μm tiled on a pitch of 66 μm. Note that even though the standard deviation associated with the subpattern changes, the projected pitch does not change.

In an embodiment a lens assembly for changing the plane of focus is placed in the projection path after the actinic radiation is reflected or transmitted by the SLM. In an embodiment, the projected pitch of the projected subpatterns from each modulation element of the first SLM at the plane of the formable material is measured and/or calculated. In an embodiment, the projected subpatterns are focused onto the plane of the formable material. In an embodiment, an object plane of an image of the modulation elements of the first SLM are within a first threshold distance of the plane of the formable material under the template.

In an embodiment, there is a second lens assembly 470b between second beam combiner 452b and the second SLM 448b. The second lens assembly 470b is configured to control a second pitch associated with the second set of projected defocused subpatterns 662₂ at the plane of the formable material while also controlling the blurriness of those subpatterns. The blurriness of the second set of projected subpatterns 662₂ can be controlled by shifting the focal plane relative to the plane of the formable material while also controlling the magnification at the plane of the formable material so that the first pitch and the second pitch match or are within 10% of each other.

FIG. 6E is an illustration of a simulated combined actinic radiation pattern 660e in which the first simulated actinic radiation pattern 660a and the third defocused simulated actinic radiation pattern 660d are overlaid over each other. The radiation patterns (660a and 660d) are aligned such that the second set of center points 664_{c,2} of the second set of defocused subpatterns 668₂ of the third defocused simulated actinic radiation pattern 660d are substantially aligned with the first set of interstitial points 664_{p,1} of the first simulated actinic radiation pattern 660a as described above.

In an embodiment, individual modulation elements 548a of the first SLM 448a and the second SLM 448b may have different modulation such that there is a spatial distribution of the dosage of actinic radiation received by the formable material. In an embodiment, the spatial distribution of the dosage of actinic radiation is controlled by adjusting, the duty cycle of modulation elements of DMD type SLM. In an embodiment, the spatial distribution of the dosage of actinic radiation is controlled by adjusting, the duty cycle and transmissivity of modulation elements of a transmissive type SLM (such as an LCD). In an embodiment, the spatial distribution of the dosage of actinic radiation is controlled by adjusting, the duty cycle and reflectivity of modulation elements of a reflective type SLM (such as an LCoS).

FIG. 6E is an illustration of a simulated combined actinic radiation pattern 660e. in which the first set of focused subpatterns 662₁ from the first SLM 448a and the second set of defocused subpatterns 668₂ from the second SLM 448b. The first set of focused subpatterns 662₁ has a focal plane that is close to the plane of the formable material. In an embodiment, the beamlet spots associated with the first set of focused subpatterns 662₁ is less than a pitch of the first set of focused subpatterns 662₁. In an embodiment, the second set of defocused subpatterns 668₂ have a focal plane that is farther from the formable material than the focal plane of the first set of focused subpatterns 662₁. In an embodiment, beamlet spots associated with the second set of defocused subpatterns 668₂ is greater than a pitch of the first set of focused subpatterns 662₁. In an embodiment, beamlet spots associated with the second set of defocused subpatterns 668₂ is greater than a pitch of the second set of focused subpatterns 662₂. In an embodiment, beamlet spots associated with the second set of defocused subpatterns 668₂ is greater than beamlet spots associated with the first set of focused subpatterns 662₁ as illustrated in FIGS. 6A and 6D-E. In an embodiment, beamlet spots associated with the second set of defocused subpatterns 668₂ are inset away from the mesa sidewalls 246 a greater distance than beam spots associated with the first set of focused subpatterns 662₁ as illustrated in FIGS. 6A and 6D-E.

One method of controlling extrusions relies on controlling the amount of actinic radiation received by the formable material near the mesa sidewalls. One method of characterizing the spatial distribution of the actinic radiation received by the formable material near the mesa sidewalls is the amount of blur associated with each modulation element of the actinic radiation produced at the plane of the formable material. The amount of blur depends on: the reflective properties of each spatial light modulator; the divergence of the actinic radiation incident on the spatial light modulator; the optical performance of the one or more optical components which guide the actinic radiation to the formable material; and the distance of the focal plane of the one or more optical components from the plane of the formable material. Some blur is tolerable and even advantageous. The effect that blur has on extrusion control depends on several factors, such as the local intensity at the mesa sidewalls 246, total applied dose, formable material curing properties; sensitivity of the formable material to the wavelength of the actinic radiation; gas environment near the mesa sidewalls 246; spectral distribution of the actinic radiation; etc.

The actinic radiation sources are configured to illuminate the SLMs with a broad beam of actinic radiation. The SLMs then transform the broad beam of actinic radiation into a set of beamlets. Each beamlet in the set of beamlets is associated with the then guided to the formable material by one or more optical components. Each beamlet may be approximated by an ideal gaussian beamlet that propagates along an optical path until it reaches the formable material. For each ideal gaussian beamlet there is an image plane intersecting with the optical that in which the beam waist of the ideal gaussian beamlet is at a minimum. Adjusting the size of the beamlet spot then depends on the distance of the image plane from the plane of the formable material.

FIG. 6F is an illustration of a cross section of 5 simulated subpatterns of actinic radiation at the plane of the formable material (solid line) and a simulated cumulative dosage of actinic radiation at the plane of the formable material (dash-dot line) produced by the five modulation elements at the plane of the formable material under the patterning surface 112 from a single spatial light modulator. The spatial distribution of the actinic radiation is approximated with a gaussian distribution of actinic radiation with a standard deviation of 18 μm and a 66 μm pitch. Note that the variation in the cumulative dosage between a center point and an interstitial point is 50%. FIG. 6G is an illustration of the arrangement of one standard deviation intensity contours of 25 simulated subpatterns of actinic radiation at the plane of the formable material.

FIG. 6H is an illustration of a cross section of 5 simulated subpatterns of actinic radiation at the plane of the formable material (solid line) from the first SLM; 4 simulated subpatterns of actinic radiation at the plane of the formable material from the second SLM (dotted line); and a cumulative dosage of actinic radiation produced by five modulation elements from the first SLM and 4 modulation elements of the second SLM at the plane of the formable material under the patterning surface 112 (dash-dot line). The spatial distribution of the actinic radiation is approximated with a gaussian distribution of actinic radiation with a standard deviation of 20 μm and a 66 μm pitch. Note that the variation in the cumulative dosage between a center point and an interstitial point is reduced to 15% while the decay rate of the dosage near the mesa sidewalls is unaffected. FIG. 6I is an illustration of the arrangement of one standard deviation intensity contours of 25 simulated subpatterns of actinic radiation from the first SLM and 16 simulated subpatterns of action radiation from the second SLM both at the plane of the formable material.

Further modifications and alternative embodiments of various aspects will be apparent to those skilled in the art in view of this description. Accordingly, this description is to be construed as illustrative only. It is to be understood that the forms shown and described herein are to be taken as examples of embodiments. Elements and materials may be substituted for those illustrated and described herein, parts and processes may be reversed, and certain features may be utilized independently, all as would be apparent to one skilled in the art after having the benefit of this description.

What is claimed is:

1. An imprinting system configured to cure formable material between a substrate and a template, the system comprising:
a first spatial light modulator with a first set of modulation elements configured to expose the formable material between the substrate and the template to a first pattern of actinic radiation; and
a second spatial light modulator with a second set of modulation elements configured to expose the formable material between the substrate and the template to a second pattern of actinic radiation; and
wherein at a plane of the formable material, a first set of centers of the first pattern associated with centers of the first set of modulation elements are offset from a second set of centers of the second pattern associated with centers of the second set of modulation elements.

2. The imprinting system according to claim 1, wherein the first pattern is in focus at the plane of the formable material and the second pattern is not in focus at the plane of the formable material.

3. The imprinting system according to claim 2, wherein a difference between a first projected pitch of the first pattern at the plane of the formable material and a second projected pitch of the second pattern at the plane of the formable material is less than 10% of the first projected pitch.

4. The imprinting system according to claim 1, wherein the first pattern at the plane of the formable material includes a first set of interstitial points;
wherein each of the interstitial points in the first set of interstitial points is located equidistant between groups of neighboring subpatterns of the first set of centers; and
wherein the second set of centers are aligned with the first set of interstitial points at the plane of the formable material.

5. The imprinting system according to claim 4, wherein an average distance between the first set of interstitial point and the second set of centers is less than 10% of an average projected pitch of the first pattern at the plane of the formable material.

6. The imprinting system according to claim 1, wherein the first spatial light modulator and the second light modulator each include: a digital micromirror device (DMD); a liquid crystal on silicon (LCoS) device; or a liquid crystal display (LCD).

7. The imprinting system according to claim 1, further comprising:
a beam combiner; and
wherein the beam combiner combines actinic radiation from the first spatial light modulator and actinic radiation from the second spatial light modulator into a combined beam;
wherein the combined beam is guided to the formable material between the template and the substrate.

8. The imprinting system according to claim 7, wherein at the beam combiner, the first set of centers are offset from the second set of centers.

9. The imprinting system according to claim 7, further comprising:
one or more optical components positioned between the first spatial light modulator and the beam combiner;
wherein the first pattern of actinic radiation includes a first set of subpatterns, each particular subpattern in the first set of subpatterns is associated with a particular modulation element of the first spatial light modulator;
wherein the second pattern of actinic radiation includes a second set of subpatterns, each particular subpattern in the second set of subpatterns is associated a particular modulation element of the second spatial light modulator;
wherein the one or more optical components are configured to control a first average size of subpatterns in the first set of subpatterns to be greater than a second average size of subpatterns in the second set of subpatterns.

10. The imprinting system according to claim 9, wherein the one or more optical components are configured to control a difference between a first projected pitch of the first pattern at the plane of the formable material and a second projected pitch of the second pattern at the plane of the formable material to be less than 10% of the first projected pitch.

11. The imprinting system according to claim 1, wherein a first average image plane of the modulation elements of the first spatial light modulator is positioned a first distance from the plane of the formable material;
wherein a second average image plane of the modulation elements of the second spatial light modulator is positioned a second distance from the plane of the formable material;
wherein the second distance is greater than the first distance.

12. The imprinting system according to claim 11, wherein a first average projected pitch at the plane of the formable material of modulation elements of the first spatial light modulator is within 10% of a second average projected pitch at the plane of the formable material of modulation elements of the second spatial light modulator.

13. The imprinting system according to claim 1, further comprising:
a template chuck configured to hold the template;
a substrate chuck configured to hold the substrate;
a dispensing system configured to dispense the formable material onto the substrate;
a positioning system configured to bring the template into contact with formable material;
a first actinic radiation emitter configured to illuminate the first spatial light modulator;
a second actinic radiation emitter configured to illuminate the second spatial light modulator; and
a third actinic radiation emitter configured to illuminate formable material between template and the substrate with actinic radiation which has not been modulated by the first spatial light modulation and the second light modulator.

14. An imprinting method configured to cure formable material between a substrate and a template, the method comprising:
exposing the formable material between the substrate and the template to a first pattern of actinic radiation from a first spatial light modulator with a first set of modulation elements; and
exposing the formable material between the substrate and the template to a second pattern of actinic radiation from a second spatial light modulator with a second set of modulation elements;
wherein at a plane of the formable material, a first set of centers of the first pattern associated with centers of the first set of modulation elements are offset from a second set of centers of the second pattern associated with centers of the second set of modulation elements.

15. A method of manufacturing an article using the imprinting method according to claim 14, the method of manufacturing an article further comprising:
processing the cured formable material on the substrate; and
forming the article from the processed substrate.
